(19) United States
(12) Patent Application Publication
(10) Pub. No.: US 2025/0037773 A1
(43) Pub. Date: Jan. 30, 2025

(54) READ VOLTAGE OVERDRIVE IN READ RECOVERY

(71) Applicant: Micron Technology, Inc., Boise, ID (US)

(72) Inventors: Ching-Huang Lu, Fremont, CA (US); Xiangyu Yang, Portland, OR (US); Yingda Dong, Los Altos, CA (US)

(21) Appl. No.: 18/781,618

(22) Filed: Jul. 23, 2024

Related U.S. Application Data
(60) Provisional application No. 63/529,464, filed on Jul. 28, 2023.

(51) Int. Cl. G11C 16/26; G11C 11/56; G11C 16/04; G11C 16/08

(52) U.S. Cl. CPC G11C 16/26; G11C 11/5671; G11C 16/0483; G11C 16/08

(57) ABSTRACT

Apparatuses, systems, and methods for applying a read voltage overdrive. One example apparatus can include an array of memory cells and a controller coupled to the array of memory cells, wherein the controller is configured to apply a pass voltage to a wordline in the array of memory cells, apply a read voltage to the wordline, and apply a read voltage overdrive greater than the read voltage and less than or equal to the pass voltage to the wordline.

### CROSS-REFERENCE TO RELATED APPLICATION

This application claims the benefit of U.S. Provisional Application No. 63/529,464, filed on Jul. 28, 2023, the contents of which are incorporated herein by reference.

### TECHNICAL FIELD

The present disclosure relates generally to memory devices, and more particularly, to apparatuses, methods, and systems for applying a read voltage overdrive in read recovery.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, phase change random access memory (PCRAM), resistive random access memory (RRAM), and magnetic random access memory (MRAM), among others.

Memory devices can be combined together to form a solid state drive (SSD). An SSD can include non-volatile memory, e.g., NAND flash memory and/or NOR flash memory, and/or can include volatile memory, e.g., DRAM and/or SRAM, among various other types of non-volatile and volatile memory. Flash memory devices can include memory cells storing data in a charge storage structure such as a floating gate, for instance, and may be utilized as non-volatile memory for a wide range of electronic applications. Flash memory devices typically use a one-transistor memory cell that allows for high memory densities, high reliability, and low power consumption.

An SSD can be used to replace hard disk drives as the main storage volume for a computer, as the solid state drive can have advantages over hard drives in terms of performance, size, weight, ruggedness, operating temperature range, and power consumption. For example, SSDs can have superior performance when compared to magnetic disk drives due to their lack of moving parts, which may avoid seek time, latency, and other electro-mechanical delays associated with magnetic disk drives.

Memory is utilized as volatile and non-volatile data storage for a wide range of electronic applications. Non-volatile memory may be used in, for example, personal computers, portable memory sticks, digital cameras, cellular telephones, portable music players such as MP3 players, movie players, and other electronic devices. Memory cells can be arranged into arrays, with the arrays being used in memory devices.

Memory cells in an array architecture can be programmed to a desired state. For instance, electric charge can be placed on or removed from the charge storage structure, e.g., floating gate, of a memory cell to program the cell to a particular state. For example, a single level (memory) cell (SLC) can be programmed to one of two different states, each representing a different digit of a data value, e.g., a 1 or 0. Some flash memory cells can be programmed to one of more than two states corresponding to different particular data values, e.g., 1111, 0111, 0011, 1011, 1001, 0001, 0101, 1101, 1100, 0100, 0000, 1000, 1010, 0010, 0110, or 1110. Such cells may be referred to as multi state memory cells, multiunit cells, or multilevel (memory) cells (MLCs). MLCs can provide higher density memories without increasing the number of memory cells since each cell can be programmed to states corresponding to more than one digit, e.g., more than one bit of data.

### BRIEF DESCRIPTION OF THE DRAWINGS

FIG. 1 is a block diagram of an apparatus in the form of a computing system including at least one memory system in accordance with some embodiments of the present disclosure.

FIG. 2 illustrates a schematic diagram of a portion of a non-volatile memory array in accordance with a number of embodiments of the present disclosure.

FIG. 3 is a graph of voltages applied to a wordline over time in accordance with a number of embodiments of the present disclosure.

FIG. 4 is a graph of voltages applied to a wordline over time in accordance with a number of embodiments of the present disclosure.

FIG. 5 is graph of voltages applied to a wordline over time mapped to poly channel traps in accordance with a number of embodiments of the present disclosure.

FIG. 6 is a flow diagram of a method for applying a read voltage overdrive in accordance with a number of embodiments of the present disclosure.

### DETAILED DESCRIPTION

Apparatuses, systems, and methods for applying a read voltage overdrive in read recovery are provided herein. In a number of embodiments of the present disclosure, an apparatus can include an array of memory cells and a controller coupled to the array of memory cells, wherein the controller is configured to apply a pass voltage to a wordline in the array of memory cells, apply a read voltage to the wordline, and apply a read voltage overdrive greater than the read voltage and less than or equal to the pass voltage to the wordline. The read voltage overdrive can be applied prior to a subsequent read voltage to retrap electrons inside a channel to reduce voltage drops and/or read window budget loss.

Polysilicon is commonly used as a channel material in 3D-Nand flash products. The electron traps inside a polysilicon channel, e.g., poly channel, or at a polysilicon interface, e.g., poly interface, can impact a read window budget. In triple level cell (TLC) and/or quad-level cell (QLC) read sequences, read voltages on a wordline applied during read operations can function as read voltage underdrives. These read voltages can cause detrapping of electrons, which can lead to voltage drops and/or read window budget loss.

Read voltage overdrive has been used in read operations to help a wordline settle and gain read time margin. For example, in prior approaches read voltage overdrive trims in read recoveries are the same as the read voltage overdrive trims in normal read operations. However, in a number of embodiments of the present disclosure, a strong read voltage overdrive, significantly larger than the read voltage overdrive trims used in normal read operations, is used in read recovery to recover read window budget loss. An enlarged read voltage overdrive and an enlarged precharge time can be used in all reads during read recovery in TLC and QLC read sequences.

In the following detailed description of the present disclosure, reference is made to the accompanying drawings that form a part hereof, and in which is shown by way of illustration how a number of embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

As used herein, “a number of” something can refer to one or more of such things. For example, a number of wordlines can refer to one or more wordlines. Additionally, designators such as “M” and “N”, as used herein, particularly with respect to reference numerals in the drawings, indicates that a number of the particular feature so designated can be included with a number of embodiments of the present disclosure.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

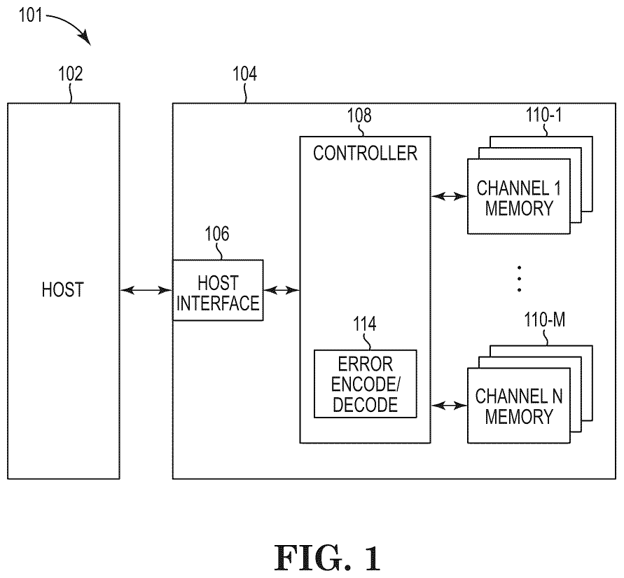

FIG. 1 is a block diagram of an apparatus in the form of a computing system 101 including at least one memory system 104 in accordance with a number of embodiments of the present disclosure. As used herein, a memory system 104, a controller 108, or a memory device 110 might also be separately considered an “apparatus”. The memory system 104 can be a solid state drive (SSD), for instance, and can include a host interface 106, a controller 108, e.g., a processor and/or other control circuitry, and a number of memory devices 110-1, . . . , 110-M, e.g., solid state memory devices such as NAND flash devices and/or three-dimensional (3D) NAND devices, which provide a storage volume for the memory system 104. In a number of embodiments, the controller 108, a memory device 110-1, . . . , 110-M, and/or the host interface 106 can be physically located on a single die or within a single package, e.g., a managed NAND application. Also, in a number of embodiments, a memory, e.g., memory devices 110-1, . . . , 110-M, can include a single memory device.

As illustrated in FIG. 1, the controller 108 can be coupled to the host interface 106 and to the memory devices 110-1, . . . , 110-M via a plurality of channels and can be used to transfer data between the memory system 104 and a host 102. The host interface 106 can be in the form of a standardized interface. For example, when the memory system 104 is used for data storage in a computing system, the host interface 106 can be a serial advanced technology attachment (SATA), peripheral component interconnect express (PCIe), or a universal serial bus (USB), among other connectors and interfaces. In general, however, host interface 106 can provide an interface for passing control, address, data, and other signals between the memory system 104 and a host 102 having compatible receptors for the host interface 106.

Host 102 can be a host system such as a personal laptop computer, a desktop computer, a digital camera, a mobile telephone, or a memory card reader, among various other types of hosts. Host 102 can include a system motherboard and/or backplane and can include a number of memory access devices, e.g., a number of processors.

The controller 108 can communicate with the memory devices 110-1, . . . , 110-M to control data read, write, and erase operations, among other operations. The controller 108 can include, for example, a number of components in the form of hardware and/or firmware, e.g., one or more integrated circuits, and/or software for controlling access to the number of memory devices 110-1, . . . , 110-M and/or for facilitating data transfer between the host 102 and memory devices 110-1, . . . , 110-M. For instance, in the example illustrated in FIG. 1, the controller 108 includes an error correcting code encoder/decoder component 114. However, the controller 108 can include various other components not illustrated so as not to obscure embodiments of the present disclosure. Also, the component 114 may not be components of controller 108, in some embodiments, e.g., component 114 can be independent components.

The error correcting code encoder/decoder component 114 can be an LDPC encoder/decoder, for instance, which can encode/decode user data transferred between host 102 and the memory devices 110-1, . . . , 110-M.

The memory devices 110-1, . . . , 110-M can include a number of arrays of memory cells. The arrays can be flash arrays with a NAND architecture, for example. However, embodiments are not limited to a particular type of memory array or array architecture. The memory cells can be grouped, for instance, into a number of blocks including a number of physical pages. A number of blocks can be included in a plane of memory cells and an array can include a number of planes. As one example, a memory device may be configured to store 8 KB (kilobytes) of user data per page, 128 pages of user data per block, 2048 blocks per plane, and 16 planes per device.

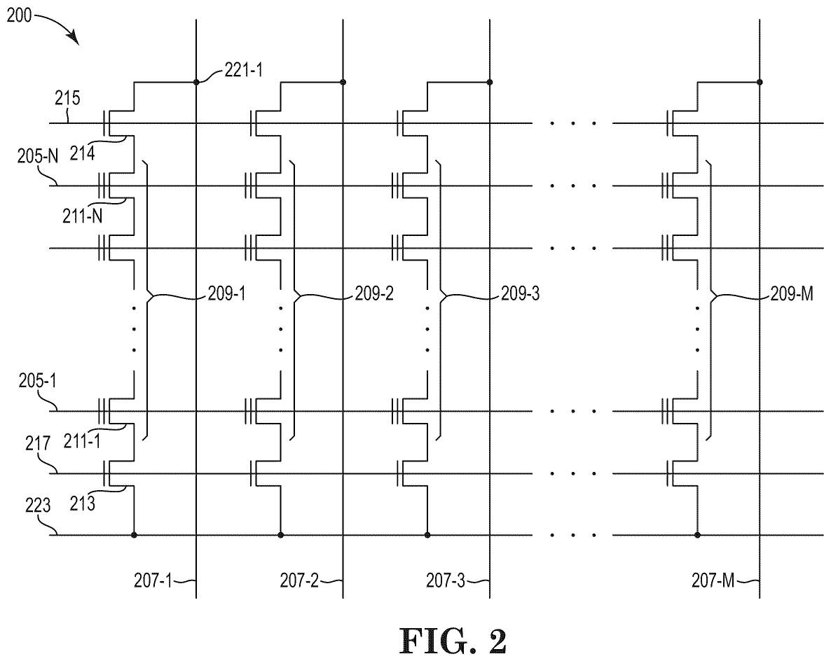

FIG. 2 illustrates a schematic diagram of a portion of a non-volatile memory array 200 in accordance with a number of embodiments of the present disclosure. The embodiment of FIG. 2 illustrates a NAND architecture non-volatile memory array, e.g., NAND Flash. However, embodiments described herein are not limited to this example. As shown in FIG. 2, memory array 200 includes access lines, e.g., wordlines 205-1, . . . , 205-N, and intersecting data lines, e.g., local bit lines, 207-1, 207-2, 207-3, . . . , 207-M. For ease of addressing in the digital environment, the number of wordlines 205-1, . . . , 205-N and the number of local bit lines 207-1, 207-2, 207-3, . . . , 207-M can be some power of two, e.g., 256 word lines by 4,096 bit lines.

Memory array 200 includes NAND strings 209-1, 209-2, 209-3, . . . 209-M. Each NAND string includes non-volatile memory cells 211-1, . . . , 211-N, each communicatively coupled to a respective wordline 205-1, . . . , 205-N. Each NAND string (and its constituent memory cells) is also associated with a local bit line 207-1, 207-2, 207-3, . . . , 207-M. The non-volatile memory cells 211-1, . . . , 211-N of each NAND string 209-1, 209-2, 209-3, . . . , 209-M are connected in series source to drain between a source select gate (SGS), e.g., a field-effect transistor (FET), 213, and a drain select gate (SGD), e.g., FET, 214. Each source select gate 213 is configured to selectively couple a respective NAND string to a common source 223 responsive to a signal on source select line 217, while each drain select gate 214 is configured to selectively couple a respective NAND string to a respective bit line responsive to a signal on drain select line 215.

As shown in the embodiment illustrated in FIG. 2, a source of source select gate 213 is connected to a common source line 223. The drain of source select gate 213 is connected to the source of the memory cell 211-1 of the corresponding NAND string 209-1. The drain of drain select gate 214 is connected to bit line 207-1 of the corresponding NAND string 209-1 at drain contact 221-1. The source of drain select gate 214 is connected to the drain of the last memory cell 211-N, e.g., a floating-gate transistor, of the corresponding NAND string 209-1.

In a number of embodiments, construction of non-volatile memory cells 211-1, . . . , 211-N includes a source, a drain, a charge storage structure such as a floating gate, and a control gate. Non-volatile memory cells 211-1, . . . , 211-N have their control gates coupled to a wordline, 205-1, . . . , 205-N respectively. A “column” of the non-volatile memory cells, 211-1, . . . , 211-N, make up the NAND strings 209-1, 209-2, 209-3, . . . , 209-M, and are coupled to a given local bit line 207-1, 207-2, 207-3, . . . , 207-M, respectively. A “row” of the non-volatile memory cells are those memory cells commonly coupled to a given wordline 205-1, . . . , 205-N. The use of the terms “column” and “row” is not meant to imply a particular linear, e.g., vertical and/or horizontal, orientation of the non-volatile memory cells. A NOR array architecture would be similarly laid out, except that the string of memory cells would be coupled in parallel between the select gates.

Subsets of cells coupled to a selected wordline, e.g., 205-1, . . . , 205-N, can be programmed and/or read together as a page of memory cells. A programming operation, e.g., a write operation, can include applying a number of program pulses, e.g., 16V-20V, to a selected word line in order to increase the threshold voltage (Vt) of selected cells coupled to that selected access line to a desired program voltage level corresponding to a target, e.g., desired, state, e.g., charge storage state. State is equivalently referred to as “level” herein.

A read operation, which can also refer to a program verify operation, can include sensing a voltage and/or current change of a bit line coupled to a selected cell in order to determine the state of the selected cell. The states of a particular fractional bit memory cell may not correspond directly to a data value of the particular memory cell, rather the states of a group of memory cells including the particular memory cell together map to a data value having an integer number of bits. The read operation can include pre-charging a bit line and detecting the discharge when a selected cell begins to conduct.

Determining, e.g., detecting, the state of a selected cell can include providing a number of sensing signals, e.g., read voltages, to a selected word line while providing a number of voltages, e.g., read pass voltages, to the word lines coupled to the unselected cells of the string sufficient to place the unselected cells in a conducting state independent of the threshold voltage of the unselected cells. The bit line corresponding to the selected cell being read and/or verified can be detected to determine whether or not the selected cell conducts in response to the particular sensing signal applied to the selected word line. For example, the state of a selected cell can be determined by the word line voltage at which the bit line current reaches a particular reference current associated with a particular state.

MLCs can be two-bit, e.g., four-state, memory cells, or store more than two bits of data per memory cell, including fractional bits of data per memory cell. For example, a two-bit memory cell can be programmed to one of four states, e.g., P0, P1, P2, and P3, respectively. In operation, a number of memory cells, such as in a selected block, can be programmed such that they have a Vt level corresponding to either P0, P1, P2, or P3. As an example, state P0 can represent a stored data value such as binary “11”. State P1 can represent a stored data value such as binary “10”. State P2 can represent a stored data value such as binary “00”. State P3 can represent a stored data value such as binary “01”. However, embodiments are not limited to these data value correspondence.

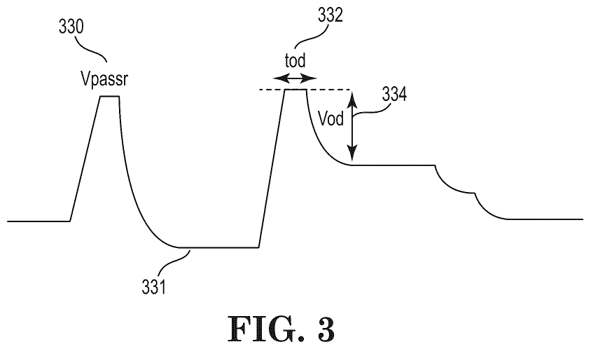

FIG. 3 is a graph of voltages applied to a wordline over time in accordance with a number of embodiments of the present disclosure. During a read operation, at 330 a read pass voltage, e.g., pass voltage, is applied to the wordline. The read voltage overdrive is applied at 334 and the time it takes to apply the read voltage overdrive is illustrated at 332. Overdrive time (t_{od}) 332 can start when the read voltage overdrive starts to ramp after applying a read voltage, e.g., read voltage 331, until the read voltage overdrive has settled to reach the next read voltage in the read sequence. A read voltage can be applied between the pass voltage and the read voltage overdrive at 331.

Where triple level cells (TLCs) and/or quad-level cells (QLCs) are included in the wordline, read voltages on the wordline can act like read voltage underdrives. These read voltages can cause detrapping of electrons, which can lead to voltage drops and/or read window budget loss.

An enlarged read voltage overdrive can be applied to perform a read recovery on a wordline including TLCs and/or QLCs. The read recovery can include a read retry, a soft bit read, and/or a corrective read, for example. A read recovery can be initiated and/or a read voltage overdrive can be applied to the wordline after a read voltage is applied to a wordline when a number of errors are identified and/or when the number of errors exceed a threshold number of errors.

The traps can be refilled with electrons by applying the read voltage overdrive. For TLCs, the read window budget can be increased by greater than 50 millivolts (mV) by applying a read voltage overdrive. By applying a read voltage overdrive to QLCs, the read window budget can be increased by greater than 190 mV.

The read voltage overdrive can be greater than a read voltage. In some examples, the read voltage overdrive can be equal to the pass voltage to ensure the read voltage overdrive is greater than a 16th voltage state of a QLC. In a number of embodiments, the read voltage overdrive can be greater than the highest read voltage applied to the wordline.

Trim settings, other than the read voltage overdrive, can be changed in response to identifying a number of errors, the number of errors exceeding a threshold number of errors, and/or initiating a read recovery. For example, a precharge time can be increased as a change to trim settings. Since a higher voltage is being applied to a wordline for read voltage overdrive, it can take longer for the voltage to ramp up to the read voltage overdrive and ramp down from the read voltage overdrive. The precharge time can be increased accordingly to include the longer ramp up and ramp down time. For example, the precharge time can be increased to greater than 2 microseconds if the wordline includes TLCs. When the wordline includes QLCs, the precharge time can be increased to greater than 5 microseconds. The precharge time can be greater for wordlines including QLCs than TLCs because QLCs have more levels.

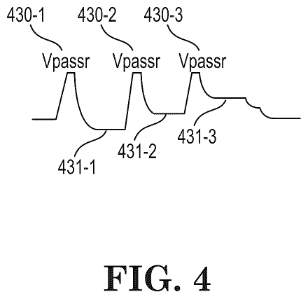

FIG. 4 is a graph of voltages applied to a wordline over time in accordance with a number of embodiments of the present disclosure. FIG. 4 illustrates voltages applied to a wordline in a read operation, such as a forward read sequence. For example, a first read voltage, e.g., a lower page read voltage, is applied at 431-1, a second read voltage, e.g., an upper page read voltage, is applied at 431-2, and a third read voltage, e.g., an extra page read voltage, is applied at 431-3. The read sequence can include any number of read voltages that are applied to the wordline.

A read voltage overdrive, which can be the same as a pass voltage can be applied between the read voltages. For example, a pass voltage can be applied at 430-1, followed by a first read voltage, e.g., a lower page read voltage, that can be applied at 431-1, followed by the pass voltage that can be applied at 430-2, followed by a second read voltage, e.g., an upper page read voltage, that can be applied at 431-2, followed by the pass voltage that can be applied at 430-3, and then a third read voltage, e.g., the extra page read voltage, can be applied at 431-3. The read sequence can include any number of read voltages that are applied to the wordline, where a pass voltage is applied to the wordline between each of the read voltages in the read sequence.

A pass voltage can be used as a read voltage overdrive because the pass voltage is greater than the highest read voltage applied to a wordline. Accordingly, a pass voltage can be used as a read voltage overdrive to ensure the read voltage overdrive is sufficient to recover read window budget loss. However, in a number of embodiments, the read voltage overdrive may not need to be as high as the pass voltage to recover read window budget loss and in some examples, a read voltage overdrive greater than the pass voltage could lead to read disturb. As such, a read voltage overdrive during a recovery operation can be greater than a highest read voltage applied to the wordline and equal to or less than a pass voltage applied to the wordline.

A read voltage overdrive can also be applied to reverse read sequences. For example, an extra page read voltage can be applied, a read voltage overdrive can be applied, an upper page read voltage can be applied, the read voltage overdrive can be applied, and a lower page read voltage can be applied.

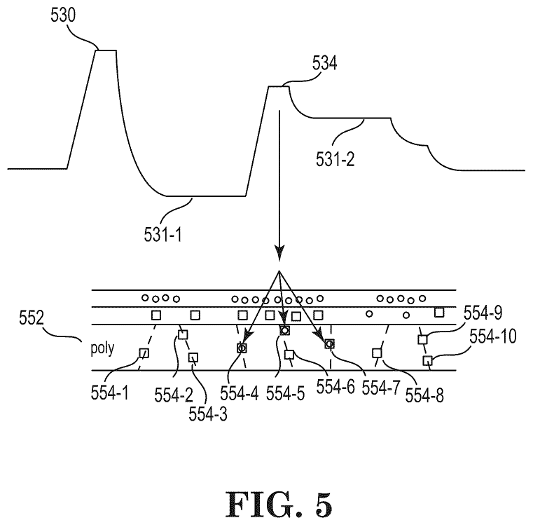

FIG. 5 is a graph of voltages applied to a wordline over time mapped to a poly channel 552 including traps 554-1, 554-2, 554-3, 554-4, 554-5, 554-6, 554-7, 554-8, 554-9, and 554-10 in accordance with a number of embodiments of the present disclosure.

Polysilicon is commonly used as a channel material in 3D-Nand flash products including a 3D NAND device. The traps 554-1, . . . , 554-10 inside a poly channel 552 or at a poly interface can impact a read window budget. In triple level cell (TLC) and/or quad-level cell (QLC) read sequences, previous read voltages on a wordline can act as read voltage underdrives. These previous read voltages can cause detrapping of electrons, which can lead to voltage drops and read window budget loss.

As illustrated in FIG. 5, a pass voltage can be applied to a wordline at 530. At 531-1 a first read voltage can be applied to the wordline. A read voltage overdrive can be applied to the wordline at 534. At 531-2 a second read voltage can be applied to the wordline.

In response to the first read voltage being applied to the wordline at 531-1, traps 554-1, 544-2, and 554-3 can be detrapped. No electrons or fewer electrons are in the poly channel 552 due to the first read voltage being applied at 531-1. At 534 the read voltage overdrive is applied to the wordline and traps 544-4, 544-5, and 554-7 are refilled with electrons. In a number of embodiments, a number of traps may remain unfilled even after a read voltage overdrive is applied. For example, trap 554-6 may remain unfilled, but could have been refilled had a greater read voltage overdrive been applied. Trap 554-6 could have been refilled had the read voltage overdrive been equal to the pass voltage applied at 530, for example. In response to the second read voltage being applied to the wordline at 531-2, traps 554-8, 554-9, and 554-10 can be detrapped leaving no electrons or fewer electrons in the poly channel 552 due to the second read voltage.

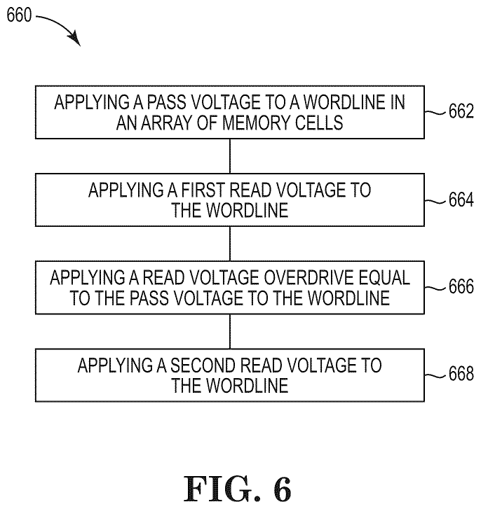

FIG. 6 is a flow diagram of a method 660 for applying a read voltage overdrive in accordance with a number of embodiments of the present disclosure. At block 662, the method 660 can include applying a pass voltage to a wordline in an array of memory cells, as illustrated at 330 in FIGS. 3 and 530 in FIG. 5. Applying a pass voltage to the wordline can place unselected cells in a conducting state.

At block 664, the method 660 can include applying a first read voltage to the wordline, as illustrated at 531-1 in FIG. 5. The method 660 can further include causing detrapping of electrons in response to applying the first read voltage to the wordline. Accordingly, a read window budget can be decreased when the first read voltage is applied to the wordline.

At block 666, the method 660 can include applying a read voltage overdrive equal to the pass voltage to the wordline, as illustrated at 334 in FIGS. 3 and 534 in FIG. 5. The method 660 can further include settling the wordline when the read voltage overdrive is applied to the wordline. In some examples, a precharge time can be increased in response to applying the read voltage overdrive.

At block 668, the method 660 can include applying a second read voltage to the wordline, as illustrated at 531-2 in FIG. 5. Detrapping of electrons and read window budget loss can again occur in response to applying the second read voltage to the wordline.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
an array of memory cells; and
a controller coupled to the array of memory cells, wherein the controller is configured to:
apply a pass voltage to a wordline in the array of memory cells;
apply a read voltage to the wordline; and
apply a read voltage overdrive greater than the read voltage and less than or equal to the pass voltage to the wordline.

2. The apparatus of claim 1, wherein the controller is configured to apply the read voltage overdrive to perform a read recovery.

3. The apparatus of claim 2, wherein the read recovery includes at least one of a read retry, a soft bit read, or a corrective read.

4. The apparatus of claim 1, wherein the wordline includes triple level cells (TLCs).

5. The apparatus of claim 4, wherein the controller is configured to increase a read window budget by greater than 50 mV in response to applying the read voltage overdrive to TLCs.

6. The apparatus of claim 1, wherein the wordline includes quad-level cells (QLCs).

7. The apparatus of claim 6, wherein the controller is configured to increase a read window budget by greater than 190 mV in response to applying the read voltage overdrive to QLCs.

8. An apparatus, comprising:
an array of non-volatile memory cells; and
a controller coupled to the array of non-volatile memory cells, wherein the controller is configured to:
apply a read voltage to a wordline in the array of non-volatile memory cells;
identify a number of errors in response to applying the read voltage to the wordline; and
apply a read voltage overdrive to the wordline greater than the read voltage and greater than a highest read voltage applied to the wordline in response to the number of errors exceeding a threshold number of errors.

9. The apparatus of claim 8, wherein the apparatus is a three-dimensional NAND (3D NAND) device.

10. The apparatus of claim 9, wherein the 3D NAND device includes polysilicon (poly) channel traps.

11. The apparatus of claim 10, wherein the applied read voltage causes detrapping of electrons in the poly channel traps.

12. The apparatus of claim 8, wherein the controller is configured to change trim settings in response to the number of errors exceeding the threshold number of errors.

13. The apparatus of claim 12, wherein the controller is configured to change trim settings by increasing a precharge time.

14. The apparatus of claim 13, wherein the precharge time is greater than 2 microseconds in response to the wordline including triple level cells (TLCs).

15. The apparatus of claim 13, wherein the precharge time is greater than 5 microseconds in response to the wordline including quad-level cells (QLCs).

16. A method, comprising:
applying a pass voltage to a wordline in an array of memory cells;
applying a first read voltage to the wordline;
applying a read voltage overdrive equal to the pass voltage to the wordline; and
applying a second read voltage to the wordline.

17. The method of claim 16, further comprising causing detrapping of electrons in response to applying the first read voltage to the wordline.

18. The method of claim 16, further comprising decreasing a read window budget in response to applying the first read voltage to the wordline.

19. The method of claim 16, further comprising settling the wordline in response to applying the read voltage overdrive.

20. The method of claim 16, further comprising increasing a precharge time in response to applying the read voltage overdrive.
